(19) United States
(12) Patent Application Publication
(10) Pub. No.: US 2013/0154069 A1
(43) Pub. Date: Jun. 20, 2013

(54) SEMICONDUCTOR PACKAGE

(71) Applicants: Tae Hoon Kim, Gyunggi-do (KR); Seog Moon Choi, Gyunggi-do (KR)

(72) Inventors: Tae Hoon Kim, Gyunggi-do (KR); Seog Moon Choi, Gyunggi-do (KR)

(73) Assignee: SAMSUNG ELECTRO-MECHANICS CO., LTD., Gyunggi-do (KR)

(21) Appl. No.: 13/584,143

(22) Filed: Aug. 13, 2012

(30) Foreign Application Priority Data
Dec. 16, 2011 (KR) 10-2011-0136667

(51) Int. Cl. H01L 23/495

(52) U.S. Cl. 257/675; 257/E23.051

(57) ABSTRACT

Disclosed herein is a semiconductor package, including: a first heat dissipation substrate; a first lead frame that is formed on the first heat dissipation substrate by patterning; a first semiconductor device formed on the first lead frame; a second semiconductor device that is stacked on the first semiconductor device; a second lead frame that is patterned and bonded to the second semiconductor device; and a second heat dissipation substrate formed on the first lead frame.

### CROSS REFERENCE TO RELATED APPLICATION

This application claims the benefit of Korean Patent Application No. 10-2011-0136667, filed on Dec. 16, 2011, entitled “Semiconductor Package”, which is hereby incorporated by reference in its entirety into this application.

### BACKGROUND OF THE INVENTION

1. Technical Field

The present invention relates to a semiconductor package.

2. Description of the Related Art

As electronics industries for power supply develop, the focus on providing compact and highly dense power semiconductor modules is increasing. Thus, in addition to reducing the size of a semiconductor device, the overall module also has to be compact. However, when a device is integrated in limited space, heat generation is increased, and such heat generation affects an operation and lifetime of a power semiconductor module, and thus is a critical issue.

A semiconductor package as described above is formed by attaching a plurality of semiconductor devices onto a single substrate formed of an insulating substrate by soldering, and coupling a housing case thereonto. In addition, the semiconductor device and the substrate and the substrate and terminals inserted into the housing are respectively connected by wire bonding or soldering. Also, a heat dissipation plate for dissipating heat of a semiconductor package is disposed only below the package, and thus it is difficult to efficiently dissipate heat (Korean Patent Laid-Open Publication No. 10-2011-0014867).

### SUMMARY OF THE INVENTION

The present invention has been made in an effort to provide a semiconductor package having a compact size.

The present invention has been made in an effort to provide a semiconductor package with improved reliability.

The present invention has been made in an effort to provide a semiconductor package with improved heat dissipation effects.

According to a preferred embodiment of the present invention, there is provided a semiconductor package comprising: a first heat dissipation substrate; a first lead frame that is formed on the first heat dissipation substrate by patterning; a first semiconductor device formed on the first lead frame; a second semiconductor device that is stacked on the first semiconductor device; a second lead frame that is patterned and bonded to the second semiconductor device; and a second heat dissipation substrate formed on the first lead frame.

The first semiconductor device may be a power device.

The first semiconductor device may be an insulated gate bipolar transistor (IGBT).

The second semiconductor device may be a control device.

The second semiconductor device may be a diode.

The semiconductor package may further include a housing that surrounds both sides of the first heat dissipation substrate and the second heat dissipation substrate to block inner space formed by the first heat dissipation substrate and the second heat dissipation substrate from the outside.

The semiconductor package may further include a first spacer formed between the first semiconductor device and the second lead frame.

The semiconductor package may further include an insulating resin filled in an inner space formed by the first heat dissipation substrate and the second heat dissipation substrate.

According to another preferred embodiment of the present invention, there is provided a semiconductor package including: a first heat dissipation substrate; a first lead frame that is formed on the first heat dissipation substrate by patterning; a first semiconductor device formed on the first lead frame; a second semiconductor device that is stacked on the first semiconductor device; a second lead frame that is patterned and bonded to the second semiconductor device; a second heat dissipation substrate formed on the first lead frame; a third lead frame that is formed on the second heat dissipation substrate by patterning; a third semiconductor device formed on the third lead frame; a fourth semiconductor device that is stacked on the third semiconductor device; a fourth lead frame that is patterned and bonded to the fourth semiconductor device; and a third heat dissipation substrate formed on the fourth lead frame.

The semiconductor package may further include a housing that surrounds both sides of the first through third heat dissipation substrates so as to block inner space formed by the first through third heat dissipation substrates from the outside.

The semiconductor package may further include a first spacer formed between the first semiconductor device and the second lead frame.

The semiconductor package may further include a second spacer formed between the third lead frame and the fourth semiconductor device.

The semiconductor package may further include a first insulating resin filled in an inner space formed by the first heat dissipation substrate and the second heat dissipation substrate.

The semiconductor package may further include a second insulating resin filled in an inner space formed by the second heat dissipation substrate and the third heat dissipation substrate.

The second heat dissipation substrate may further include a through via.

The through via may electrically connect the second lead frame to the third lead frame.

The first semiconductor device and the fourth semiconductor device may be power devices.

The first semiconductor device and the fourth semiconductor device may be insulated gate bipolar transistors (IGBTs).

The second semiconductor device and the third semiconductor device may be control devices.

The second semiconductor device and the third semiconductor device may be diodes.

### BRIEF DESCRIPTION OF THE DRAWINGS

FIG. 1 is a schematic view illustrating a semiconductor package according to an embodiment of the present invention;

FIG. 2 is a schematic view illustrating a multi-layer semiconductor package according to an embodiment of the present invention;

FIG. 3 is a schematic view illustrating a multi-layer semiconductor package according to another embodiment of the present invention; and

FIG. 4 is a schematic view illustrating a multi-layer semiconductor package according to another embodiment of the present invention.

### DESCRIPTION OF THE PREFERRED EMBODIMENTS

Various features and advantages of the present invention will be more obvious from the following description with reference to the accompanying drawings.

The terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept of the term to describe most appropriately the best method he or she knows for carrying out the invention.

The above and other objects, features, and advantages of the present invention will be more clearly understood from the following detailed description taken in conjunction with the accompanying drawings. In the specification, in adding reference numerals to components throughout the drawings, it is to be noted that like reference numerals designate like components even though components are shown in different drawings.

Further, when it is determined that the detailed description of the known art related to the present invention may obscure the gist of the present invention, the detailed description thereof will be omitted. While terms such as “first,” “second,” etc., may be used to describe various components, such terms are used only to distinguish one component from another, and the components must not be limited to the above terms.

Hereinafter, preferred embodiments of the present invention will now be described with reference to the attached drawings.

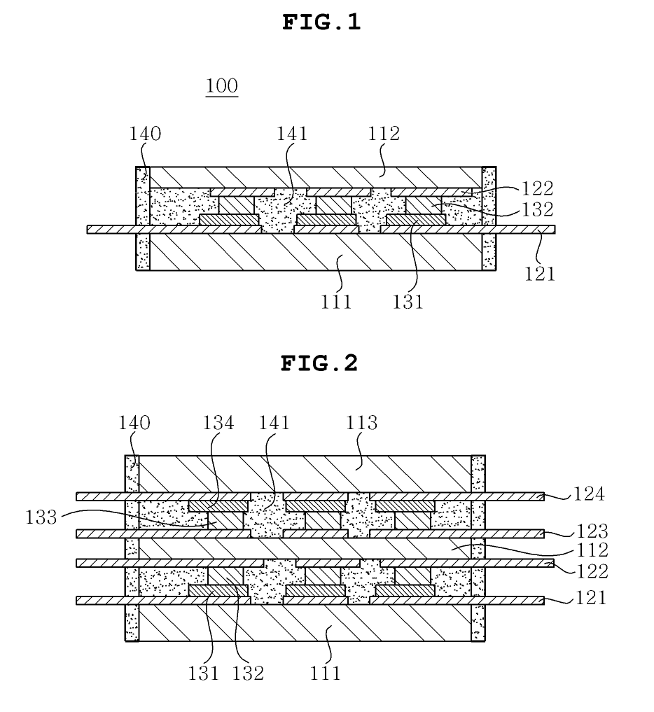

FIG. 1 is a schematic view illustrating a semiconductor package 100 according to an embodiment of the present invention.

Referring to FIG. 1, the semiconductor package 100 may include a first heat dissipation substrate 111, a first lead frame 121, a first semiconductor device 131, a second semiconductor device 132, a second lead frame 122, a second heat dissipation substrate 112, and a housing 140.

The first heat dissipation substrate 111 may be disposed in a lower portion of the semiconductor package 100. The first heat dissipation substrate 111 may be formed of a metal having a high thermal conductivity. The first heat dissipation substrate 111 may dissipate heat generated in the semiconductor package 100 to the outside.

The first lead frame 121 may be formed on the first heat dissipation substrate 111. The first lead frame 121 may be electrically connected to the first semiconductor device 131. The first lead frame 121 may be formed of an electrically conductive metal. Also, the first lead frame 121 may be formed of a thermally conductive metal. As described above, the first lead frame 121 formed of an electrically conductive or thermally conductive metal may transfer heat generated in the first semiconductor device 131 to the first heat dissipation substrate 111.

The first semiconductor device 131 is mounted on the first lead frame 121. The first semiconductor device 131 may be a power device. For example, the first semiconductor device may be an insulated gate bipolar transistor (IGBT). When mounting the first semiconductor device 131 on the first lead frame 121, the first semiconductor device 131 may be bonded using a conductive adhesive. The conductive adhesive may be a solder or a conductive epoxy. The second semiconductor device 132 may be mounted on the first semiconductor device 131.

The second semiconductor device 132 is mounted on the first semiconductor device 131. The second semiconductor device 132 may be a control device. For example, the second semiconductor device 132 may be a diode. When mounting the second semiconductor device 132 on the second lead frame 122, the second semiconductor device 132 may be bonded using a conductive adhesive. The conductive adhesive may be solder or conductive epoxy.

The second lead frame 122 may be formed on the second semiconductor device 132. The second lead frame 122 may be electrically connected to the second semiconductor device 132. The second lead frame 122 may be formed of an electrically conductive metal. Also, the second lead frame 122 may be formed of a thermally conductive metal. As described above, the second lead frame 122 formed of an electrically conductive or thermally conductive metal may transfer heat generated in the second semiconductor device 132 to the second heat dissipation substrate 112.

At least one of the first lead frame 121 and the second lead frame 122 according to the current embodiment of the present invention may be formed to protrude from the housing 140. Also, the first lead frame 121 and the second lead frame 122 according to the current embodiment of the present invention may be patterned according to design. When the first lead frame 121 and the second lead frame 122 are patterned according to design, the first semiconductor device 131 and the second semiconductor device 132 may be electrically connected to each other.

The second heat dissipation substrate 112 may be disposed in an upper portion of the semiconductor package 100. That is, the second heat dissipation substrate 112 may be formed on the second lead frame 122. The second heat dissipation substrate 112 may be formed of a metal having high thermal conductivity. The second heat dissipation substrate 112 may dissipate heat generated in the semiconductor package 100 to the outside.

The housing 140 may be formed to block inner space formed between the first heat dissipation substrate 111 and the second heat dissipation substrate 112 and components included therein, from the outside. The housing 140 may be formed in various forms to block components included inside from the outside. For example, the housing 140 may be formed to have a structure in which sides of the first heat dissipation substrate 111 and the second heat dissipation substrate 112 are surrounded to separate inside and outside of the housing 140. Also, the housing 140 may have a structure in which all sides of the first heat dissipation substrate 111 and the second heat dissipation substrate 112 are surrounded to separate inside and outside of the housing 140. The housing 140 formed as described above may be filled with an insulating resin 141 in order to protect the components included inside.

According to an embodiment of the present invention, the first semiconductor device 131 and the second semiconductor device 132 may be directly stacked on each other. By directly stacking the first semiconductor device 131 and the second semiconductor device 132 on each other and electrically connecting them, the semiconductor package 100 having a compact size may be manufactured.

FIG. 2 is a schematic view illustrating a multi-layer semiconductor package 100 according to an embodiment of the present invention.

Referring to FIG. 2, the multi-layer semiconductor package 100 may include first through third heat dissipation substrates 111 through 113, first through fourth lead frames 121 through 124, first through fourth semiconductor devices 131 through 134, and a housing 140.

The first heat dissipation substrate 111 may be disposed in a lower portion of the multi-layer semiconductor package 100. The first heat dissipation substrate 111 may be formed of a metal having a high thermal conductivity. The first heat dissipation substrate 111 may dissipate heat generated in the multi-layer semiconductor package 100 to the outside.

The first lead frame 121 may be formed on the first heat dissipation substrate 111. The first lead frame 121 may be electrically connected to the first semiconductor device 131. The first lead frame 121 may be formed of an electrically conductive metal. Also, the first lead frame 121 may be formed of a thermally conductive metal. As described above, the first lead frame 121 formed of an electrically conductive or thermally conductive metal may transfer heat generated in the first semiconductor device 131 to the first heat dissipation substrate 111.

The first semiconductor device 131 is mounted on the first lead frame 121. The first semiconductor device 131 may be a power device. For example, the first semiconductor device may be an IGBT. When mounting the first semiconductor device 131 on the first lead frame 121, the first semiconductor device 131 may be bonded using a conductive adhesive. The conductive adhesive may be solder or conductive epoxy. The second semiconductor device 132 may be mounted on the first semiconductor device 131.

The second semiconductor device 132 is mounted on the first semiconductor device 131. The second semiconductor device 132 may be a control device. For example, the second semiconductor device 132 may be a diode. The second lead frame 122 may be mounted on the second semiconductor device 132. As described above, the second semiconductor device 132 may be electrically connected to the first semiconductor device 131 by being stacked on the first semiconductor device 131.

The second lead frame 122 may be formed on the second semiconductor device 132. The second lead frame 122 may be electrically connected to the second semiconductor device 132. The second lead frame 122 may be formed of an electrically conductive metal. Also, the second lead frame 122 may be formed of a thermally conductive metal. As described above, the second lead frame 122 formed of an electrically conductive or thermally conductive metal may transfer heat generated in the second semiconductor device 132 to the second heat dissipation substrate 112.

The second heat dissipation substrate 112 may be formed on the second lead frame 122. The second heat dissipation substrate 112 may be formed of a metal having a high thermal conductivity.

The third lead frame 123 may be formed on the second heat dissipation substrate 112. The third lead frame 123 may be electrically connected to the third semiconductor device 133. The third lead frame 123 may be formed of an electrically conductive metal. Also, the third lead frame 123 may be formed of a thermally conductive metal. As described above, the third lead frame 123 formed of an electrically conductive or thermally conductive metal may transfer heat generated in the third semiconductor device 133 to the second heat dissipation substrate 112.

The third semiconductor device 133 is mounted on the third lead frame 123. The third semiconductor device 133 may be a control device. For example, the third semiconductor device 133 may be a diode. The fourth semiconductor device 134 may be mounted on the third semiconductor device 133. When mounting the third semiconductor device 133 on the third lead frame 123, the third semiconductor device 133 may be bonded using a conductive adhesive. The conductive adhesive may be solder or conductive epoxy.

The fourth semiconductor device 134 is mounted on the third semiconductor device 133. For example, the fourth semiconductor device 134 may be a power device. The fourth semiconductor device 134 may be an IGBT. As described above, the fourth semiconductor device 134 may be electrically connected to the third semiconductor device 133 by being stacked on the third semiconductor device 133.

The fourth lead frame 124 may be formed on the fourth semiconductor device 134. The fourth lead frame 124 may be electrically connected to the fourth semiconductor device 134. The fourth lead frame 124 may be formed of an electrically conductive metal. Also, the fourth lead frame 124 may be formed of a thermally conductive metal. As described above, the fourth lead frame 124 formed of an electrically conductive or thermally conductive metal may transfer heat generated in the fourth semiconductor device 134 to the third heat dissipation substrate 113.

At least one of the first through fourth lead frames 121 through 124 according to the current embodiment of the present invention may be formed to protrude from the housing 140. Also, the first through fourth lead frames 121 through 124 according to the current embodiment of the present invention may be patterned according to design. When the first through fourth lead frames 121 through 124 are patterned according to design, the first through fourth semiconductor devices 131 through 134 may be electrically connected to one another.

The third heat dissipation substrate 113 may be disposed in an upper portion of the multi-layer semiconductor package 100. That is, the third heat dissipation substrate 113 may be formed on the fourth lead frame 124. The third heat dissipation substrate 113 may be formed of a metal having a high thermal conductivity. The third heat dissipation substrate 113 may dissipate heat generated in the multi-layer semiconductor package 100 to the outside.

The housing 140 may be formed to block inner space formed between the first through third heat dissipation substrates 111 through 113 and components included therein from the outside. The housing 140 may be formed in various forms to block components included therein from the outside. For example, the housing 140 may be formed to have a structure in which sides of the first through third heat dissipation substrates 111 through 113 are surrounded to separate inside and outside of the housing 140. Also, the housing 140 may have a structure in which external surfaces of the first through third heat dissipation substrates 111 through 113 that are exposed to the outside are surrounded to separate inside and outside of the housing 140. The housing 140 formed as described above may be filled with an insulating resin 141 in order to protect the components included inside.

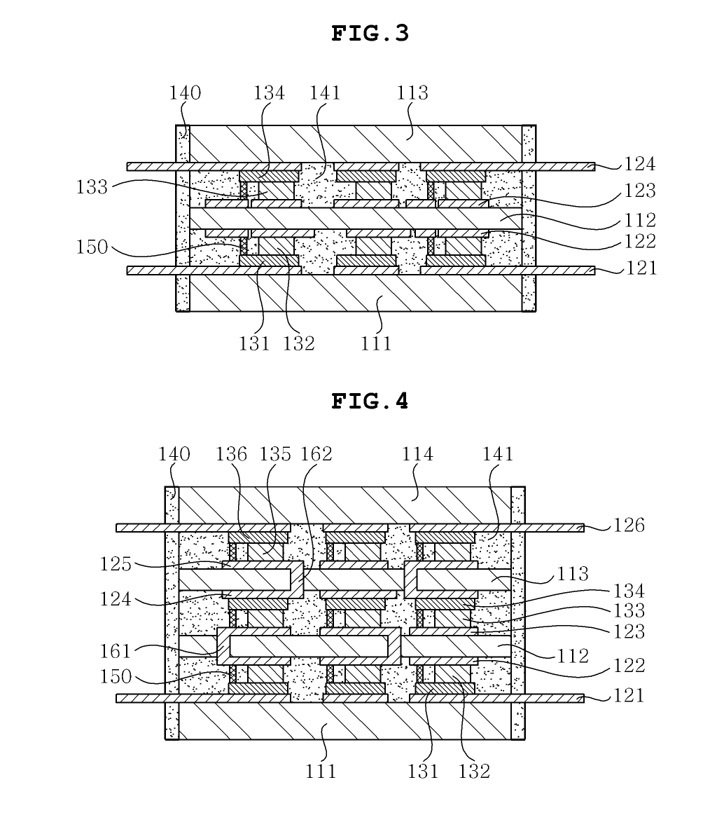

FIG. 3 is a schematic view illustrating a multi-layer semiconductor package 100 according to another embodiment of the present invention.

Referring to FIG. 3, the multi-layer semiconductor package 100 may include first through third heat dissipation substrates 111 through 113, first through fourth lead frames 121 through 124, first through fourth semiconductor devices 131 through 134, a spacer 150, and a housing 140.

The first heat dissipation substrate 111 may be disposed in a lower portion of the multi-layer semiconductor package 100. The first heat dissipation substrate 111 may be formed of a metal having high thermal conductivity to dissipate heat generated in the multi-layer semiconductor package 100 to the outside.

The first lead frame 121 may be formed on the first heat dissipation substrate 111. The first lead frame 121 may be formed of an electrically conductive metal to be electrically connected to the first semiconductor device 131. Also, the first lead frame 121 may be formed of a thermally conductive metal to transfer heat generated in the first semiconductor device 131 to the first heat dissipation substrate 111.

The first semiconductor device 131 is mounted on the first lead frame 121. The first semiconductor device 131 may be a power device. For example, the first semiconductor device 131 may be an IGBT.

The second semiconductor device 132 is mounted on the first semiconductor device 131. The second semiconductor device 132 may be a control device. For example, the second semiconductor device 132 may be a diode. The second semiconductor device 132 may be electrically connected to the first semiconductor device 131 by being stacked on the first semiconductor device 131.

The second lead frame 122 may be formed on the second semiconductor device 132. The second lead frame 122 may be formed of an electrically conductive metal to be electrically connected to the second semiconductor device 132. Also, the second lead frame 122 may be formed of a thermally conductive metal to transfer heat generated in the second semiconductor device 132 to the second heat dissipation substrate 112.

The second heat dissipation substrate 112 may be formed on the second lead frame 122. The second heat dissipation substrate 112 may be formed of a metal having a high thermal conductivity.

The third lead frame 123 may be formed on the second heat dissipation substrate 112. The third lead frame 123 may be formed of an electrically conductive metal to be electrically connected to the third semiconductor device 133. Also, the third lead frame 123 may be formed of a thermally conductive metal to transfer heat generated in the third semiconductor device 133 to the second heat dissipation substrate 112.

The third semiconductor device 133 is mounted on the third lead frame 123. The third semiconductor device 133 may be a control device. For example, the third semiconductor device 133 may be a diode.

The fourth semiconductor device 134 is mounted on the third semiconductor device 133. The fourth semiconductor device 134 may be a power device. For example, the fourth semiconductor device 134 may be an IGBT. As described above, the fourth semiconductor device 134 may be electrically connected to the third semiconductor device 133 by being stacked on the third semiconductor device 133.

The fourth lead frame 124 may be formed on the fourth semiconductor device 134. The fourth lead frame 124 may be formed of an electrically conductive metal to be electrically connected to the fourth semiconductor device 134. Also, the fourth lead frame 124 may be formed of a thermally conductive metal to transfer heat generated in the fourth semiconductor device 134 to the third heat dissipation substrate 113.

At least one of the first through fourth lead frames 121 through 124 according to the current embodiment of the present invention may be formed to protrude from the housing 140. Also, the first through fourth lead frames 121 through 124 according to the current embodiment of the present invention may be patterned according to design. When the first through fourth lead frames 121 through 124 are patterned according to design, the first through fourth semiconductor devices 131 through 134 may be electrically connected to one another.

The third heat dissipation substrate 113 may be disposed in an upper portion of the multi-layer semiconductor package 100. That is, the third heat dissipation substrate 113 may be formed on the fourth lead frame 124. The third heat dissipation substrate 113 may be formed of a metal having high thermal conductivity to dissipate heat generated in the multi-layer semiconductor package 100 to the outside.

The spacer 150 may be formed between the first semiconductor device 131 and the second lead frame 122. The spacer 150 may be formed according to design when the first semiconductor device 131 and the second lead frame 122 are to be electrically connected to each other. Also, the spacer 150 may be formed to help ensure structural stability due to different sizes of the first semiconductor device 131 and the second semiconductor device 132. The first semiconductor device 131 and the second semiconductor device 132 may have different sizes. For example, the first semiconductor device 131 may have a larger surface area than the second semiconductor device 132. In this case, a stack structure of the first semiconductor device 131 and the second semiconductor device 132 may be unstable and problems such as partial sinking of the multi-layer semiconductor package 100 may occur. In order to ensure structural stability, the spacer 150 may be formed at a portion where the first semiconductor device 131 is positioned but not where the second semiconductor device 132 contacts.

If the spacer 150 is included to electrically connect the first semiconductor device 131 to the second lead frame 122, it may be formed of an electrically conductive metal. Also, if the spacer 150 is included for structural support and not for electrical connection between the first semiconductor device 131 and the second lead frame 122, it may be formed of an electrically non-conductive metal.

The spacer 150 may also be formed between the fourth semiconductor device 134 and the third lead frame 123 for the above-described, same reason.

The housing 140 may be formed to block inner space formed between the first through third heat dissipation substrates 111 through 113 and components included therein, from the outside. The housing 140 may be formed in various forms to block components included inside from the outside. For example, the housing 140 may be formed to have a structure in which sides of the first through third heat dissipation substrates 111 through 113 are surrounded to separate inside and outside of the housing 140. Also, the housing 140 may have a structure in which external surfaces of the first through third heat dissipation substrates 111 through 113 that are exposed to the outside are surrounded to separate inside and outside of the housing 140. The housing 140 formed as described above may be filled with an insulating resin 141 in order to protect the components included inside.

FIG. 4 is a schematic view illustrating a multi-layer semiconductor package 100 according to another embodiment of the present invention.

Referring to FIG. 4, the multi-layer semiconductor package 100 may include first through fourth heat dissipation substrates 111 through 114, first through sixth lead frames 121 through 126, first through sixth semiconductor devices 131 through 136, a spacer 150, and a housing 140.

The first heat dissipation substrate 111 may be disposed in a lower portion of the multi-layer semiconductor package 100. The first heat dissipation substrate 111 may be formed of a metal having high thermal conductivity to dissipate heat generated in the multi-layer semiconductor package 100 to the outside.

The first lead frame 121 may be formed on the first heat dissipation substrate 111. The first lead frame 121 may be formed of an electrically conductive metal to be electrically connected to the first semiconductor device 131. Also, the first lead frame 121 may be formed of a thermally conductive metal to transfer heat generated in the first semiconductor device 131 to the first heat dissipation substrate 111.

The first semiconductor device 131 is mounted on the first lead frame 121. The first semiconductor device 131 may be a power device. For example, the first semiconductor device 131 may be an IGBT.

The second semiconductor device 132 is mounted on the first semiconductor device 131. The second semiconductor device 132 may be a control device. For example, the second semiconductor device 132 may be a diode. The second semiconductor device 132 may be electrically connected to the first semiconductor device 131 by being stacked on the first semiconductor device 131.

The second lead frame 122 may be formed on the second semiconductor device 132. The second lead frame 122 may be formed of an electrically conductive metal to be electrically connected to the second semiconductor device 132. Also, the second lead frame 122 may be formed of a thermally conductive metal to transfer heat generated in the second semiconductor device 132 to the second heat dissipation substrate 112.

The second heat dissipation substrate 112 may be formed on the second lead frame 122. The second heat dissipation substrate 112 may be formed of a metal having a high thermal conductivity. A first through via 161 may be formed in the second heat dissipation substrate 112. The first through via 161 may be formed to pass through the second heat dissipation substrate 112. The first through via 161 may be formed of an electrically conductive metal. Also, the first through via 161 may be formed of a thermally conductive metal. The first through via 161 may electrically connect the third lead frame 123 formed on the second heat dissipation substrate 112 to the second lead frame 122 formed below the second heat dissipation substrate 112. Also, the first through via 161 may be used as a heat dissipation path between the second lead frame 122 and the third lead frame 123.

The third lead frame 123 may be formed on the second heat dissipation substrate 112. The third lead frame 123 may be formed of an electrically conductive metal to be electrically connected to the third semiconductor device 133. Also, the third lead frame 123 may be formed of a thermally conductive metal to transfer heat generated in the third semiconductor device 133 to the second heat dissipation substrate 112.

The third semiconductor device 133 is mounted on the third lead frame 123. The third semiconductor device 133 may be a control device. For example, the third semiconductor device 133 may be a diode.

The fourth semiconductor device 134 is mounted on the third semiconductor device 133. The fourth semiconductor device 134 may be a power device. For example, the fourth semiconductor device 134 may be an IGBT. As described above, the fourth semiconductor device 134 may be electrically connected to the third semiconductor device 133 by being stacked on the third semiconductor device 133.

The fourth lead frame 124 may be formed on the fourth semiconductor device 134. The fourth lead frame 124 may be formed of an electrically conductive metal to be electrically connected to the fourth semiconductor device 134. Also, the fourth lead frame 124 may be formed of a thermally conductive metal to transfer heat generated in the fourth semiconductor device 134 to the third heat dissipation substrate 113.

The third heat dissipation substrate 113 may be formed on the fourth lead frame 124. The third heat dissipation substrate 113 may be formed of a metal having high thermal conductivity. A second through via 162 may be formed in the third heat dissipation substrate 113. The second through via 162 may be formed to pass through the third heat dissipation substrate 113. The second through via 162 may be formed of an electrically conductive metal. Also, the second through via 162 may be formed of a thermally conductive metal. The second through via 162 may electrically connect the fifth lead frame 125 formed on the third heat dissipation substrate 113 to the fourth lead frame 124 formed below the third heat dissipation substrate 113. Also, the second through via 162 may be used as a heat dissipation path between the fourth lead frame 124 and the fifth lead frame 125.

The fifth lead frame 125 may be formed on the third heat dissipation substrate 113. The fifth lead frame 125 may be formed of an electrically conductive metal to be electrically connected to the fifth semiconductor device 135. Also, the fifth lead frame 125 may be formed of a thermally conductive metal to transfer heat generated in the fifth semiconductor device 135 to the third heat dissipation substrate 113.

The fifth semiconductor device 135 is mounted on the fifth lead frame 125. The fifth semiconductor device 135 may be a control device. For example, the fifth semiconductor device 135 may be a diode.

The sixth semiconductor device 136 is mounted on the fifth semiconductor device 135. The sixth semiconductor device 136 may be a power device. For example, the sixth semiconductor device 136 may be an IGBT. As described above, the sixth semiconductor device 136 may be electrically connected to the fifth semiconductor device 135 by being stacked on the fifth semiconductor device 135.

The sixth lead frame 126 may be formed on the sixth semiconductor device 136. The sixth lead frame 126 may be formed of an electrically conductive metal to be electrically connected to the sixth semiconductor device 136. Also, the sixth lead frame 126 may be formed of a thermally conductive metal to transfer heat generated in the sixth semiconductor device 136 to the fourth heat dissipation substrate 114.

At least one of the first through sixth lead frames 121 through 126 according to the current embodiment of the present invention may be protruded from the housing 140. Also, the first through sixth lead frames 121 through 126 according to the current embodiment of the present invention may be patterned according to design. When the first through sixth lead frames 121 through 126 are patterned according to design, the first through sixth semiconductor devices 131 through 136 may be electrically connected to one another.

The fourth heat dissipation substrate 114 may be disposed in an upper portion of the multi-layer semiconductor package 100. That is, the fourth heat dissipation substrate 114 may be formed on the sixth lead frame 126. The fourth heat dissipation substrate 114 may be formed of a metal having a high thermal conductivity to dissipate heat generated in the multi-layer semiconductor package 100 to the outside.

The spacer 150 may be formed between semiconductor devices and lead frames. The spacer 150 may be formed according to design when a semiconductor device and a lead frame that is not directly bonded to the semiconductor device are to be electrically connected to each other. Also, the spacer 150 may be formed to ensure structural stability due to different sizes of the stacked semiconductor devices. For example, the first semiconductor device 131 may have a larger surface area than the second semiconductor device 132. In this case, a stack structure of the first semiconductor device 131 and the second semiconductor device 132 is unstable and problems such as partial sinking of the multi-layer semiconductor package 100 may occur. In order to support the structural stability, the spacer 150 may be formed at a portion where the first semiconductor device 131 is positioned but not where the second semiconductor device 132 contacts.

If the spacer 150 is included to electrically connect the first semiconductor device 131 to the second lead frame 122, it may be formed of an electrically conductive metal. Also, if the spacer 150 is included for structural support and not for electrical connection between the first semiconductor device 131 and the second lead frame 122, it may be formed of an electrically non-conductive metal.

The housing 140 may be formed to block inner space formed between the first through fourth heat dissipation substrates 111 through 114 and components included therein, from the outside. The housing 140 may be formed in various forms to block components included therein from the outside. For example, the housing 140 may be formed to have a structure in which sides of the first through fourth heat dissipation substrates 111 through 114 are surrounded to separate inside and outside of the housing 140. Also, the housing 140 may have a structure in which external surfaces of the first through fourth heat dissipation substrates 111 through 114 that are exposed to the outside are surrounded to separate inside and outside of the housing 140. The housing 140 formed as described above may be filled with an insulating resin 141 in order to protect the components included inside.

In the multi-layer semiconductor package according to the current embodiment of the present invention, semiconductor devices may be stacked to electrically connect the same each other, and this structure may be stacked in multiple layers. Thus, the multi-layer semiconductor package having a compact size may be formed. Also, electrical connection of the multi-layer semiconductor package according to the current embodiment of the present invention is conducted using lead frames, and thus parasitic capacitance and loss, which are generated by wire bonding, are prevented, thereby improving reliability of the semiconductor package. In addition, through vias are formed on inner substrates of the multi-layer semiconductor package according to the current embodiment of the present invention so that an interlayer connection is provided. Also, heat dissipation paths having simple structures are provided by the through vias formed in the substrates disposed in the multi-layer semiconductor package according to the current embodiment of the present invention, thereby reducing heat resistance and increasing heat dissipation effects.

According to the embodiments of the present invention, a compact semiconductor package may be manufactured by stacking semiconductor devices and electrically connecting the same.

According to the embodiments of the present invention, reliability of a semiconductor package may be improved by electrically connecting semiconductor devices using lead frames.

According to the embodiments of the present invention, a through via is formed in heat dissipation substrates disposed in a semiconductor package, thereby improving heat dissipation effects by reducing heat resistance.

Although the preferred embodiments of the present invention have been disclosed for illustrative purposes, they are for specifically explaining the present invention. Therefore, a semiconductor package according to the preferred embodiments of the present invention is not limited thereto, but those skilled in the art will appreciate that various modifications and alterations are possible, without departing from the scope and spirit of the invention as disclosed in the accompanying claims.

Accordingly, such modifications and alterations should also be understood to fall within the scope of the present invention. A specific protective scope of the present invention could be defined by the accompanying claims.

What is claimed is:

1. A semiconductor package comprising:
a first heat dissipation substrate;
a first lead frame that is formed on the first heat dissipation substrate by patterning;
a first semiconductor device formed on the first lead frame;
a second semiconductor device that is stacked on the first semiconductor device;
a second lead frame that is patterned and bonded to the second semiconductor device; and
a second heat dissipation substrate formed on the first lead frame.

2. The semiconductor package as set forth in claim 1, wherein the first semiconductor device is a power device.

3. The semiconductor package as set forth in claim 1, wherein the first semiconductor device is an insulated gate bipolar transistor (IGBT).

4. The semiconductor package as set forth in claim 1, wherein the second semiconductor device is a control device.

5. The semiconductor package as set forth in claim 1, wherein the second semiconductor device is a diode.

6. The semiconductor package as set forth in claim 1, further comprising a housing that surrounds both sides of the first heat dissipation substrate and the second heat dissipation substrate to block inner space formed by the first heat dissipation substrate and the second heat dissipation substrate from the outside.

7. The semiconductor package as set forth in claim 1, further comprising a first spacer formed between the first semiconductor device and the second lead frame.

8. The semiconductor package as set forth in claim 1, further comprising an insulating resin filled in an inner space formed by the first heat dissipation substrate and the second heat dissipation substrate.

9. A semiconductor package comprising:
a first heat dissipation substrate;
a first lead frame that is formed on the first heat dissipation substrate by patterning;
a first semiconductor device formed on the first lead frame;
a second semiconductor device that is stacked on the first semiconductor device;
a second lead frame that is patterned and bonded to the second semiconductor device;
a second heat dissipation substrate formed on the first lead frame;
a third lead frame that is formed on the second heat dissipation substrate by patterning;
a third semiconductor device formed on the third lead frame;
a fourth semiconductor device that is stacked on the third semiconductor device;
a fourth lead frame that is patterned and bonded to the fourth semiconductor device; and
a third heat dissipation substrate formed on the fourth lead frame.

10. The semiconductor package as set forth in claim 9, further comprising a housing that surrounds both sides of the first through third heat dissipation substrates so as to block inner space formed by the first through third heat dissipation substrates from the outside.

11. The semiconductor package as set forth in claim 9, further comprising a first spacer formed between the first semiconductor device and the second lead frame.

12. The semiconductor package as set forth in claim 9, further comprising a second spacer formed between the third lead frame and the fourth semiconductor device.

13. The semiconductor package as set forth in claim 9, further comprising a first insulating resin filled in an inner space formed by the first heat dissipation substrate and the second heat dissipation substrate.

14. The semiconductor package as set forth in claim 9, further comprising a second insulating resin filled in an inner space formed by the second heat dissipation substrate and the third heat dissipation substrate.

15. The semiconductor package as set forth in claim 9, wherein the second heat dissipation substrate further includes a through via.

16. The semiconductor package as set forth in claim 15, wherein the through via electrically connects the second lead frame to the third lead frame.

17. The semiconductor package as set forth in claim 9, wherein the first semiconductor device and the fourth semiconductor device are power devices.

18. The semiconductor package as set forth in claim 9, wherein the first semiconductor device and the fourth semiconductor device are insulated gate bipolar transistors (IGBTs).

19. The semiconductor package as set forth in claim 9, wherein the second semiconductor device and the third semiconductor device are control devices.

20. The semiconductor package as set forth in claim 9, wherein the second semiconductor device and the third semiconductor device are diodes.
